(19) United States
(12) Patent Application Publication
(10) Pub. No.: US 2025/0364232 A1
(43) Pub. Date: Nov. 27, 2025

(54) WALL MEMBER AND PLASMA PROCESSING APPARATUS

(71) Applicant: Tokyo Electron Limited, Tokyo (JP)

(72) Inventors: Takashi TAIRA, Miyagi (JP); Ryoji BAMBA, Miyagi (JP)

(73) Assignee: Tokyo Electron Limited, Tokyo (JP)

(21) Appl. No.: 19/298,235

(22) Filed: Aug. 13, 2025

Related U.S. Application Data
(63) Continuation of application No. PCT/JP2024/005562, filed on Feb. 16, 2024.

(30) Foreign Application Priority Data
Feb. 21, 2023 (JP) 2023-024921

(51) Int. Cl. H01J 37/32

(52) U.S. Cl. CPC H01J 37/32834; H01J 37/32522; H01J 37/32715; H01J 2237/002; H01J 2237/166

(57) ABSTRACT

A wall member body is provided in a circumferential direction of a processing container, and provided with a first cavity formed along the circumferential direction inside. A pipe member is disposed in the first cavity, formed of a member having lower thermal conductivity than the wall member body, provided with a second cavity formed to flow a cooling gas inside, and provided with one or more holes formed to cause the first cavity and the second cavity to communicate with each other.

### CROSS-REFERENCE TO RELATED APPLICATIONS

This application is a continuation of International Application No. PCT/JP2024/005562, filed on Feb. 16, 2024 which claims the benefit of priority under 35 U.S.C. § 119 (a) of the prior Japanese Patent Application No. 2023-024921, filed on Feb. 21, 2023, the entire contents of each are incorporated herein by reference.

### FIELD

Exemplary embodiments disclosed herein relate to a wall member and a plasma processing apparatus.

### BACKGROUND

Japanese Laid-open Patent Publication No. 2011-124362 discloses a technology of disposing a protective plate provided with a heat medium channel inside a side wall of a main container forming a processing chamber and filling the space between the inner surface of the side wall and the protective plate with a heat insulating material to thermally separate the main container and the protective plate from each other.

### SUMMARY

In an embodiment of a present disclosure, a wall member includes: a wall member body provided in a circumferential direction of a processing container, and provided with a first cavity formed along the circumferential direction inside; and a pipe member disposed in the first cavity, formed of a member having lower thermal conductivity than the wall member body, provided with a second cavity formed to flow a cooling gas inside, and provided with one or more holes formed to cause the first cavity and the second cavity to communicate with each other.

### BRIEF DESCRIPTION OF DRAWINGS

FIG. 1 is a diagram of an example of a plasma processing apparatus in an embodiment;

FIG. 2 is a partially enlarged view of an example of a cross section of a shutter mechanism in the embodiment;

FIG. 3 is a diagram of an example of the appearance of the shutter mechanism in the embodiment;

FIG. 4 is a diagram of an example of a pipe member in the embodiment;

FIG. 5 is a diagram illustrating an example of the configuration of a valve body in the embodiment;

FIG. 6 is a diagram illustrating the flow of dry air in a cavity of the valve body in the embodiment;

FIG. 7 is a diagram illustrating the flow of the dry air in the cavity of the valve body in the embodiment; and

FIG. 8 is a diagram of an example of the structure of a side wall of a chamber in the embodiment.

### DESCRIPTION OF EMBODIMENTS

Exemplary embodiments of a wall member and a plasma processing apparatus disclosed in the present application will be explained below in detail with reference to the accompanying drawings. The present invention is not limited to the embodiments explained below.

For example, using a conventional technology, a configuration is considered in which a channel (a cavity) is formed along a circumferential direction inside a wall member of a chamber, and a cooling gas such as dry air is circulated through the channel to cool the wall member. However, when cooling is performed by circulating the cooling gas through the channel, the wall member is strongly cooled by the cooling gas near an inlet of the channel through which the cooling gas flows in, and the temperature of the cooling gas in the channel rises and cooling weakens as the distance from the inlet increases, thus causing a large temperature difference in the circumferential direction. Given this, it is expected to inhibit the temperature difference of the wall member in the circumferential direction.

### Configuration of Plasma Processing Apparatus

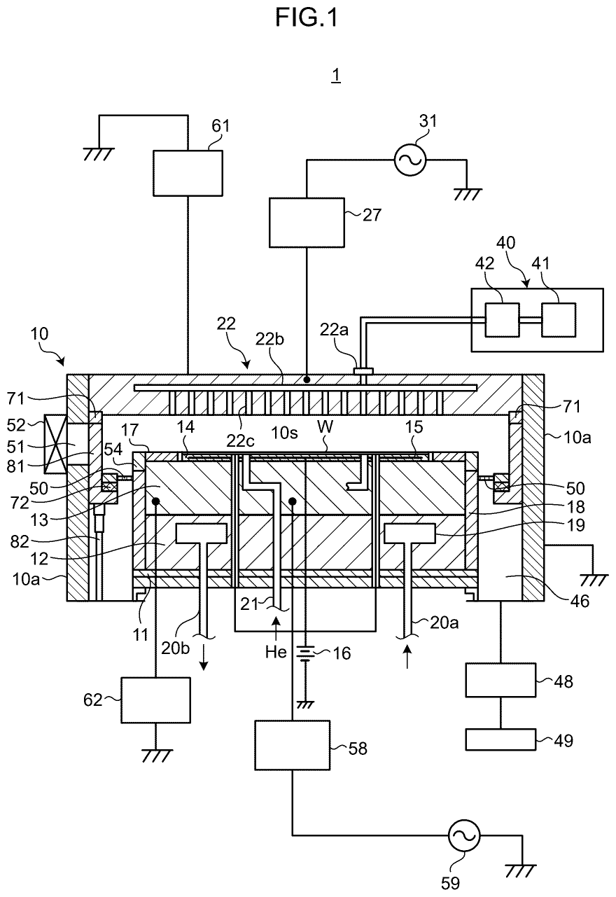

FIG. 1 is a diagram of an example of the plasma processing apparatus in the embodiment. In FIG. 1, this plasma processing apparatus 1 is configured as a capacitive coupling type parallel plate plasma etching apparatus. The plasma processing apparatus 1 includes a chamber 10. The chamber 10 is, for example, formed of surface-anodized (anodic oxidized) aluminum, and is formed in a cylindrical shape. The chamber 10 is safely grounded. However, this is not limiting. The plasma processing apparatus 1 is not limited to the capacitive coupling type parallel plate plasma etching apparatus, and may be a plasma processing apparatus of any type such as inductively coupled plasma (ICP), microwave plasma, or magnetron plasma.

A susceptor 13 is disposed in the chamber 10. At the bottom of the chamber 10, a cylindrical susceptor support stand 12 is disposed via an insulating plate 11 such as ceramic. The susceptor 13 is disposed on the susceptor support stand 12. The susceptor 13 is formed of, for example, a conductive material such as aluminum, and has a configuration functioning as a lower electrode. On the susceptor 13, a substrate to be etched, for example, a wafer W, which is a semiconductor wafer, is placed.

An electrostatic chuck (ESC) 14 to hold the wafer W by electrostatic suction is disposed on the upper surface of the susceptor 13. The electrostatic chuck 14 includes an electrode plate 15 made of a conductive film and a pair of insulating layers, which are, for example, dielectrics such as Y₂O₃, Al₂O₃, or AlN, holding the electrode plate 15 therebetween. A DC power supply 16 is electrically connected to the electrode plate 15 via a connection terminal. The electrostatic chuck 14 holds by suction the wafer W by the Coulomb force or the Johnson-Rahbek force caused by a DC voltage applied by the DC power supply 16.

A plurality of (e.g., three) pusher pins as lift pins that can protrude and retract from the upper surface of the electrostatic chuck 14 are disposed at the portion of the upper surface of the electrostatic chuck 14 where the wafer W is held by suction. These pusher pins are connected to a motor (not shown) via ball screws (not shown). The pusher pins freely protrude from the upper surface of the electrostatic chuck 14 due to the rotational motion of the motor, which has been converted into linear motion by the ball screws. With this, the pusher pins penetrate the electrostatic chuck 14 and the susceptor 13 to move up and down so as to protrude and retract in an inside space. When the electrostatic chuck 14 holds by suction the wafer W in the case of applying an etching process to the wafer W, the pusher pins are accommodated in the electrostatic chuck 14. When the wafer W subjected to the etching process is carried out of a plasma processing space 10s, the pusher pins protrude from the electrostatic chuck 14 to lift the wafer W upward away from the electrostatic chuck 14.

An edge ring 17 made of, for example, silicon is disposed on the peripheral upper surface of the susceptor 13 to improve etching uniformity. Around the edge ring 17, a cover ring 54 protecting the side of the edge ring 17 is disposed. The side surfaces of the susceptor 13 and the susceptor support stand 12 are covered with, for example, a cylindrical member 18 made of quartz.

Inside the susceptor support stand 12, for example, a refrigerant chamber 19 extending in the circumferential direction is disposed. A refrigerant, for example, cooling water at a certain temperature is circulated and supplied to the refrigerant chamber 19 via pipes 20a and 20b from an external chiller unit (not shown). The refrigerant chamber 19 controls the processing temperature of the wafer W on the susceptor 13 by the temperature of the refrigerant.

A heat transfer gas, for example, helium gas, is supplied from a heat transfer gas supply mechanism (not shown) via a gas supply line 21 between the upper surface of the electrostatic chuck 14 and the back surface of the wafer W. The heat transfer gas efficiently and uniformly controls heat transfer between the wafer W and the susceptor 13.

The plasma processing apparatus 1 includes a gas introduction unit. The gas introduction unit is configured to introduce at least one processing gas into the chamber 10. The gas introduction unit includes a shower head 22. The shower head 22 is disposed above the susceptor 13. In one embodiment, the shower head 22 forms at least part of a ceiling of the chamber 10. The chamber 10 has the plasma processing space 10s defined by the shower head 22, a side wall 10a of the chamber 10, and the susceptor 13. The chamber 10 is grounded. The shower head 22 and the susceptor 13 are electrically isolated from the housing of the chamber 10.

The plasma processing apparatus 1 includes a gas supply unit 40. The gas supply unit 40 supplies various processing gases for use in a plasma process. The shower head 22 is configured to introduce the at least one processing gas from the gas supply unit 40 into the plasma processing space 10s. The shower head 22 has at least one gas supply port 22a, at least one gas diffusion chamber 22b, and a plurality of gas introduction ports 22c. The processing gas supplied to the gas supply port 22a passes through the gas diffusion chamber 22b to be introduced into the plasma processing space 10s through the gas introduction ports 22c. In addition to the shower head 22, the gas introduction unit may include one or a plurality of side gas injectors (SGIs) mounted on one or a plurality of openings formed in the side wall 10a.

The gas supply unit 40 may include at least one gas source 41 and at least one flow controller 42. In one embodiment, the gas supply unit 40 is configured to supply the at least one processing gas to the shower head 22 from the gas source 41 corresponding to each gas via the flow controller 42 corresponding to each gas. Each flow controller 42 may include, for example, a mass flow controller or a pressure-controlled flow controller. Further, the gas supply unit 40 may include one or more flow modulating devices modulating or pulsing the flow of the at least one processing gas.

The shower head 22 includes at least one upper electrode. An upper RF power supply 31 is electrically connected to the upper electrode of the shower head 22 via an upper matching device 27. The upper matching device 27 is used to match a load impedance to the internal (or output) impedance of the upper RF power supply 31. The upper RF power supply 31 supplies RF power for plasma generation to the upper electrode of the shower head 22 via the upper matching device 27 when etching the wafer W. In one embodiment, the RF power for plasma generation has a frequency in a range of 10 MHZ to 150 MHZ. In one embodiment, the upper RF power supply 31 may be configured to generate a plurality of RF powers having different frequencies. The upper matching device 27 functions such that the output impedance of the upper RF power supply 31 and the load impedance apparently match when plasma is being generated in the chamber 10. Note that a refrigerant chamber or cooling jacket (not shown) may be provided also in the shower head 22 to control the temperature of the electrode with a refrigerant supplied from an external chiller unit (not shown).

An exhaust port 46 is provided at the bottom of the chamber 10. To the exhaust port 46, an automatic pressure control valve (hereinafter referred to as “APC valve”) 48, which is a variable butterfly valve, and a turbo molecular pump (hereinafter referred to as “TMP”) 49 are connected. The APC valve 48 and the TMP 49 work together to reduce the pressure of the plasma processing space 10s in the chamber 10 to a desired vacuum level. Between the exhaust port 46 and the plasma processing space 10s, an annular baffle plate 50 having a plurality of vent holes is disposed around the susceptor 13. The baffle plate 50 prevents plasma leakage from the plasma processing space 10s to the exhaust port 46.

In the side wall 10a of the chamber 10, an opening 51 for carrying in and carrying out the wafer W is provided, and a gate valve 52 opening and closing the opening 51 is disposed. In the chamber 10, a first deposition shield 71 and a second deposition shield 72 are detachably provided along the inner wall of the chamber 10. The first deposition shield 71 is an upper member of a deposition shield, and is provided above the opening 51 of the chamber 10. The second deposition shield 72 is a lower member of the deposition shield, and is provided below the baffle plate 50. The lower part of the first deposition shield 71 is in contact with the upper part of a valve body 81 of a shutter mechanism 80, which will be described below, to close the opening 51. The first deposition shield 71 and the second deposition shield 72 can be formed by, for example, covering an aluminum material with ceramic such as Y₂O₃. Note that the lower part of the first deposition shield 71 is covered with a conductive material, for example, stainless steel, a nickel alloy, or the like so as to enable conduction with the valve body 81 being in contact therewith.

The wafer W is carried in and carried out by opening and closing the gate valve 52. However, since the gate valve 52 is disposed outside the chamber 10 (in a transport chamber), a space is formed where the opening 51 protrudes into the transport chamber. This causes the plasma generated in the chamber 10 to diffuse to the space protruding into the transport chamber, causing deterioration of the uniformity of the plasma and deterioration of a sealing member of the gate valve 52. Thus, the valve body 81 shuts off the first deposition shield 71 and the second deposition shield 72 from each other, thereby shutting off the opening 51 of the chamber 10 and the plasma processing space 10s from each other. A lifting/lowering mechanism 82 driving the valve body 81 is disposed, for example, below the second deposition shield 72. The valve body 81 is driven up and down by the lifting/lowering mechanism 82 and opens and closes the space between the first deposition shield 71 and the second deposition shield 72, that is, the opening 51. Note that the valve body 81 and the lifting/lowering mechanism 82 may be collectively referred to as the shutter mechanism 80. The first deposition shield 71, the second deposition shield 72, and the valve body 81 are examples of an inner wall member of the chamber 10.

In the plasma processing apparatus 1, a lower RF power supply 59 is electrically connected to the susceptor 13 as the lower electrode via a lower matching device 58. The lower RF power supply 59 supplies RF power for biasing to the susceptor 13 via the lower matching device 58 when etching the wafer W. The RF power for biasing may be the same as or different from the frequency of the RF power for plasma generation. In one embodiment, the RF power for biasing has a lower frequency than the frequency of the RF power for plasma generation. In one embodiment, the RF power for biasing has a frequency in a range of 100 kHz to 60 MHz. The lower matching device 58 is used to match the load impedance to the internal (or output) impedance of the lower RF power supply 59. The lower matching device 58 functions such that the internal impedance of the lower RF power supply 59 and the load impedance apparently match when plasma is being generated in the plasma processing space 10s in the chamber 10. Another second lower RF power supply may be connected to the lower electrode.

In the plasma processing apparatus 1, a low-pass filter (LPF) 61 is electrically connected to the upper electrode of the shower head 22. The LPF 61 is configured to pass the RF power from the lower RF power supply 59 to the ground without passing the RF power from the upper RF power supply 31 to the ground. The LPF 61 preferably includes an LR filter or LC filter. However, even a single conducting wire can provide a sufficiently large reactance to the RF power from the upper RF power supply 31. As the LPF 61, only a single conducting wire may be electrically connected to the upper electrode of the shower head 22 instead of the LR filter or LC filter. Meanwhile, a high-pass filter (HPF) 62 to pass the RF power from the upper RF power supply 31 to the ground is electrically connected to the susceptor 13.

Note that the plasma processing apparatus 1 may be configured to supply the RF power for plasma generation together with the RF power for biasing to the susceptor 13 as the lower electrode during the plasma process. For example, the plasma processing apparatus 1 may be configured to electrically connect the upper RF power supply 31 to the susceptor 13 via the upper matching device 27 to supply the RF power for plasma generation from the upper RF power supply 31 together with the RF power for biasing to the susceptor 13. The lower RF power supply 59 may be configured to generate a plurality of RF powers having different frequencies. The generated one or more RF powers are supplied to the susceptor 13. In various embodiments, at least one of the RF power for biasing and the RF power for plasma generation may be pulsed.

Next, an operation when the plasma processing apparatus 1 performs etching of the wafer W will be briefly described. The plasma processing apparatus 1 makes the gate valve 52 and the valve body 81 an open state. With this, the wafer W to be processed is carried in into the chamber 10, and placed on the electrostatic chuck 14. When the wafer W is placed on the electrostatic chuck 14, the plasma processing apparatus 1 makes the gate valve 52 and the valve body 81 a closed state. The plasma processing apparatus 1 applies a DC voltage from the DC power supply 16 to the electrode plate 15 of the electrostatic chuck 14 to electrostatically adsorb the wafer W onto the susceptor 13. The plasma processing apparatus 1 introduces a processing gas for etching (e.g., a mixture gas of C₄F₈ gas and argon (Ar) gas) from the gas supply unit 40 into the plasma processing space 10s at a certain flow and flow ratio. The plasma processing apparatus 1 sets the pressure of the plasma processing space 10s in the chamber 10 by the APC valve 48 and the TMP 49 to a value suitable for etching, for example, any value in the range of several millitorrs to 1 Torr. Note that 1 Torr is 133 Pa, for example.

Furthermore, the plasma processing apparatus 1 applies the RF power for plasma generation from the upper RF power supply 31 to the shower head 22 at a certain power, and applies the RF power for biasing from the lower RF power supply 59 to the lower electrode of the susceptor 13 at a certain power.

This generates plasma in the plasma processing space 10s in the plasma processing apparatus 1. The surface to be processed of the wafer W is physically or chemically etched by radicals and/or ions generated in this process.

In the plasma processing apparatus 1, the plasma becomes dense while being in a favorable dissociation state when high-frequency waves in a high-frequency range (a frequency range in which ions cannot move) is applied to the shower head 22. In addition, high-density plasma can be formed even under lower pressure conditions.

### Details of Shutter Mechanism 80

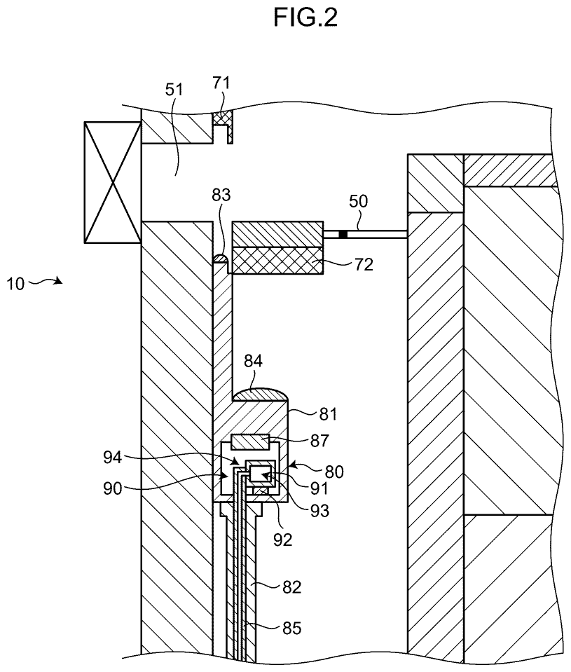

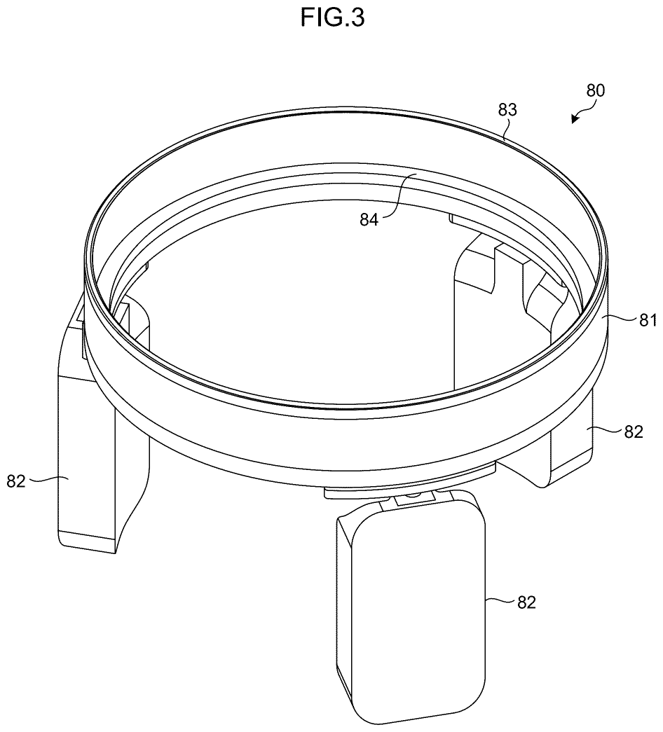

FIG. 2 is a partially enlarged view of an example of a cross section of the shutter mechanism 80 in the embodiment. FIG. 3 is a diagram of an example of the appearance of the shutter mechanism 80 in the embodiment. As illustrated in FIG. 2 and FIG. 3, the shutter mechanism 80 has the valve body 81 having at least half the length of the inner circumference of the chamber 10 and two or more lifting/lowering mechanisms 82 lifting and lowering the valve body 81. In the present embodiment, the valve body 81 is an annular valve body along the inner circumference of the chamber 10, as illustrated in FIG. 3, for example. The valve body 81 has a conductive member 83 being in contact with the first deposition shield 71 and a conductive member 84 being in contact with the second deposition shield 72 when the opening 51 is closed.

The valve body 81 is formed of, for example, an aluminum material or the like in a substantially L shape in cross section. The surface of the valve body 81 is coated with, for example, Y₂O₃ or the like. The conductive member 83 is disposed at the upper end of the valve body 81. The conductive member 84 is disposed at a step of the valve body 81. The conductive members 83 and 84, which are also called conductance bands or spirals, are conductive elastic members. For the conductive members 83 and 84, for example, stainless steel, a nickel alloy, or the like can be used. The conductive members 83 and 84 are formed by, for example, spirally winding a strip-shaped member. For the conductive members 83 and 84, for example, U-shaped jacketed diagonally wound coil springs may be used. In other words, the conductive members 83 and 84 are crushed when the valve body 81 comes in contact with the first deposition shield 71 and the second deposition shield 72.

The lifting/lowering mechanism 82 has a rod. The rod is fixed and connected to the lower part of the valve body 81 by screws or the like. The lifting/lowering mechanism 82 lifts and lowers the rod up and down by, for example, an air cylinder, a motor, or the like. In the lifting/lowering mechanism 82, when the air cylinder is used, the flows of dry air supplied to the lifting/lowering mechanisms 82 are controlled to be equal to each other. In the example in FIG. 3, three lifting/lowering mechanisms 82 are disposed at equal intervals of 120 degrees. The lifting/lowering mechanisms 82 are lifted and lowered at the same timing and speed, and can thereby lift and lower the valve body 81 without causing the valve body 81 to flex or tilt. For example, when the valve body 81 is semicircular along the inner circumference of the chamber 10, it can be lifted and lowered in the same manner by providing the lifting/lowering mechanisms 82 at both ends.

In the shutter mechanism 80, the valve body 81 is pushed upward by the lifting/lowering mechanism 82 to close the opening 51 and pulled downward by the lifting/lowering mechanism 82 to open the opening 51. When the valve body 81 closes the opening 51, the conductive members 83 and 84 disposed at the upper part and the lower part of the valve body 81 are in contact with the first deposition shield 71 and the second deposition shield 72, respectively. This causes the valve body 81 to be electrically connected to the first deposition shield 71 and the second deposition shield 72 via the conductive members 83 and 84. The first deposition shield 71 is in contact with the grounded chamber 10. Therefore, the valve body 81 is grounded via the first deposition shield 71 and the second deposition shield 72 when the opening 51 is closed.

In the shutter mechanism 80, the valve body 81 corresponds to part of a conventional deposition shield, and thus corresponds to part of the conventional deposition shield divided into a plurality of parts. The conventional deposition shield is heavy and thus difficult to work with during maintenance, but in the present embodiment, the deposition shield is divided into the first deposition shield 71, the second deposition shield 72, and the valve body 81, and thus they are easy to work with during maintenance.

The shutter mechanism 80 is temperature-controllable. Here, the shutter mechanism 80 is lifted and lowered. When a member thus lifted and lowered is to be temperature-controlled by, for example, circulating a liquid such as a temperature-controlled refrigerant, the weight will increase. In addition, relatively large equipment such as a chiller unit to temperature control and circulate the liquid is required.

Given this, in the present embodiment, a cooling gas cools the shutter mechanism 80. For example, the shutter mechanism 80 is formed with a cavity 90 along the circumferential direction of the chamber 10 inside the valve body 81. The cavity 90 is rectangular in cross section. The cavity 90 connects over one circumference along the circumferential direction of the valve body 81 to be formed in an annular shape. In the shutter mechanism 80, at least one lifting/lowering mechanism 82 is provided with a supply route and an exhaust route. The supply route is connected to an unillustrated gas supply unit such as a pump capable of supplying a cooling gas, and the cooling gas is supplied from the gas supply unit. The cooling gas is, for example, dry air. FIG. 2 illustrates a supply route 85 in the lifting/lowering mechanism 82.

In the shutter mechanism 80, a heater 87 is disposed inside the valve body 81. The heater 87 is provided on the upper surface of the cavity 90 with the lower side protruding into the cavity 90. The heater 87 is supplied with power via unillustrated wiring provided in at least one lifting/lowering mechanism 82.

The shutter mechanism 80 is made temperature-controllable by cooling it by flowing dry air through the cavity 90 and heating it by supplying power to the heater 87. The dry air may be at room temperature or cooled. The shutter mechanism 80 becomes hot due to heat input from the plasma and heating by the heater 87. Thus, the dry air, even at room temperature, is relatively low in temperature with respect to the shutter mechanism 80, and can thus cool the shutter mechanism 80.

Here, for example, the shutter mechanism 80 could be configured to cool the valve body 81 by supplying the dry air from the supply route to the cavity 90, circulating it through the cavity 90, and exhausting it from the exhaust route. However, when cooled in such a configuration, the valve body 81 is strongly cooled by the dry air near an inlet of the cavity 90 through which the dry air flows in from the supply route 85, and as the distance from the inlet increases, the temperature of the dry air becomes higher, and cooling becomes weaker, thus causing a large temperature difference in the circumferential direction.

Given this, the present embodiment is configured as follows. The valve body 81 disposes a pipe member 91 in the cavity 90. In the embodiment, the pipe member 91 is formed in a rectangular shape in its outer cross section. The pipe member 91 is, along the cavity 90 of the valve body 81, disposed in the cavity 90. The pipe member 91 is supported by supports 92 at a plurality of locations in the cavity 90. For example, the pipe member 91 is supported by the supports 92 provided at regular intervals (e.g., every 90°), and portions other than the supports 92 are separated from the inner surface of the cavity 90.

In the pipe member 91, a cavity 93 is formed to flow the cooling gas. The cavity 93 is rectangular in cross section. The cavity 93 is formed in an annular shape in the pipe member 91. The pipe member 91 is formed with a supply port 94 communicating with the cavity 93. The supply route 85 is connected to the supply port 94.

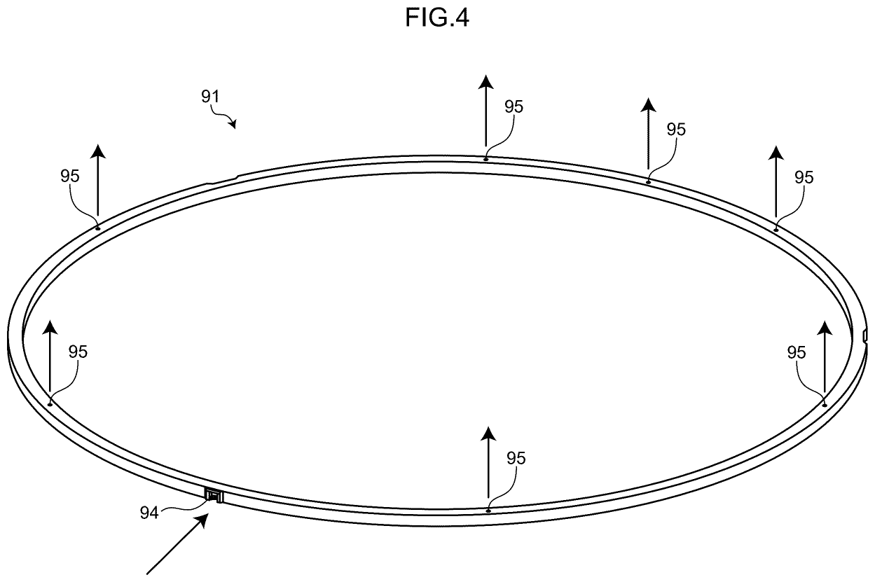

FIG. 4 is a diagram of an example of the pipe member 91 in the embodiment. The pipe member 91 connects over one circumference to be formed in an annular shape. The pipe member 91 is formed of a member having lower thermal conductivity than the valve body 81. For example, the pipe member 91 is formed of a resin such as polytetrafluoroethylene (PTFE) or polyetheretherketone (PEEK). Note that the pipe member 91 may be formed of stainless steel (SUS) or the like.

The pipe member 91 is formed with a plurality of holes 95 communicating with the cavity 93. The holes 95 are formed on the upper surface of the pipe member 91 closer to the heater. Each hole 95 blows dry air supplied to the cavity 93.

In the pipe member 91, if the sizes and spacings of the holes 95 are the same, the pressure in the cavity 93 is higher in a region closer to the supply port 94, and thus the hole 95 closer to the supply port 94 blows a larger amount of the dry air, and a region closer to the supply port 94 is more cooled.

Given this, the pipe member 91 in the embodiment adjusts at least one of the sizes of the holes 95 and the spacings of the holes 95. For example, in the pipe member 91, the diameter of the holes 95 is formed larger as the distance from the supply port 94 increases along the cavity 93. Alternatively, in the pipe member 91, the holes 95 are formed at a shorter spacing as the distance from the supply port 94 increases along the cavity 93. By increasing the diameter of the holes 95 as the distance from the supply port 94 increases along the cavity 93, the amounts of the dry air blown out of the holes 95 can be equalized. By forming the holes 95 at a shorter spacing as the distance from the supply port 94 increases along the cavity 93, the amounts of the dry air blown out of the holes 95 of the pipe member 91 can be equalized per unit length of the pipe member 91. This can inhibit the temperature difference of the valve body 81 in the circumferential direction.

Since forming the cavity 93 in an annular shape, the pipe member 91 forms the holes 95 on the upper surface at positions annularly symmetrical with respect to the supply port 94. This enables the pipe member 91 to blow the dry air having flowed through the cavity 93 from the supply port 94 out of the holes 95 at symmetrical positions, and thus the dry air can be inhibited from stagnating at the positions annularly symmetrical with respect to the supply port 94.

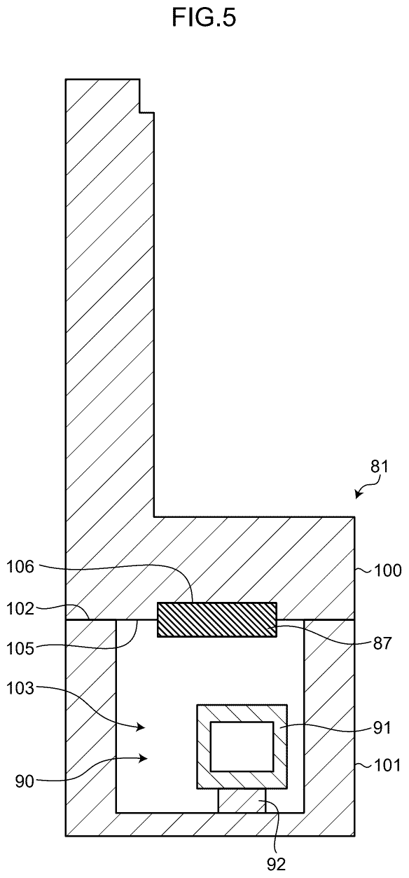

FIG. 5 is a diagram illustrating an example of the configuration of the valve body 81 in the embodiment. The valve body 81 includes an upper member 100 on the upper side and a lower member 101 on the lower side joined together. The upper member 100 and the lower member 101 are formed in an annular shape with the same diameter. The lower member 101 is formed with a groove 103 over the entire circumference along the circumferential direction on an upper surface 102 joined to the upper member 100. The pipe member 91 is disposed in the groove 103. In the upper member 100, the heater 87 is mounted on a lower surface 105 joined to the lower member 101. For example, the upper member 100 is formed with a groove 106 at a position corresponding to the groove 103. The groove 106 is formed over the entire circumference in the circumferential direction. The heater 87 is formed with a width slightly larger than the groove 106, and is mounted on the upper member 100 by being press fit into the groove 106, making it integral with the upper member 100.

The valve body 81 is manufactured, for example, as follows. The pipe member 91 is disposed in the groove 103 of the lower member 101. The heater 87 is mounted in the groove 106 of the upper member 100. Then, the lower surface 105 of the upper member 100 and the upper surface 102 of the lower member 101 are mated with each other such that the heater 87 of the upper member 100 is in the groove 103 of the lower member 101, and the lower member 101 and the upper member 100 are hermetically joined together. For example, the lower member 101 is joined to the upper member 100 by providing a sealing member such as an O-ring on the inner circumferential side and the outer circumferential side of the upper surface 102 of the lower member 101, thereby hermetically joining them together. Alternatively, the lower member 101 and the upper member 100 are hermetically sealed by welding.

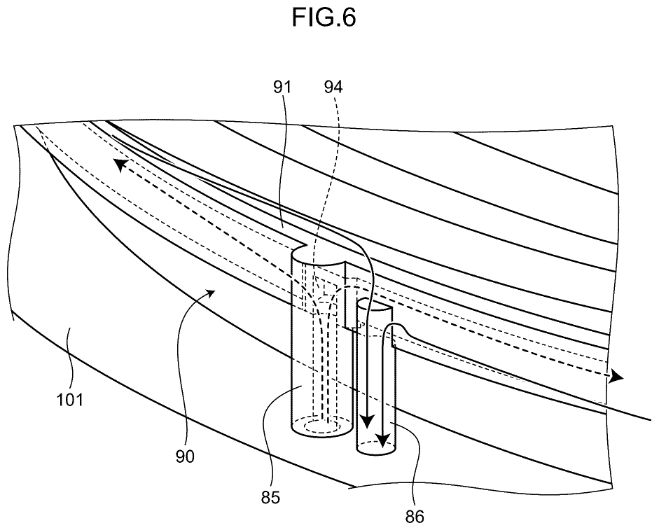

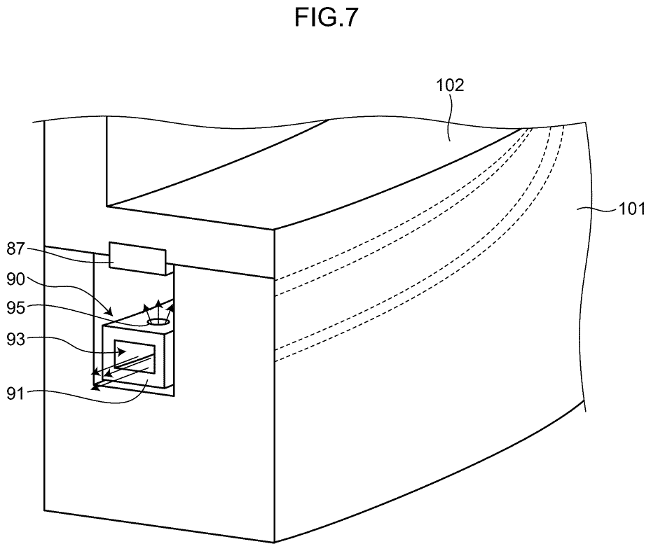

FIG. 6 and FIG. 7 are diagrams illustrating the flow of the dry air in the cavity 90 of the valve body 81 in the embodiment. FIG. 6 illustrates the supply route 85 and an exhaust route 86 provided in the lifting/lowering mechanism 82. The supply route 85 is connected to the supply port 94 of the pipe member 91. The exhaust route 86 communicates with the cavity 90. The exhaust route 86 is connected to an exhaust unit provided outside the chamber 10. The exhaust unit may be, for example, the APC valve 48 and the TMP 49 or a different exhaust device.

The dry air supplied from the supply route 85 is supplied to the supply port 94 of the pipe member 91. The dry air supplied to the supply port 94 flows through the cavity 93 of the pipe member 91, and blows out of the holes 95 into the cavity 90. Since the pipe member 91 is formed with the holes 95 at a plurality of positions in the circumferential direction, the dry air blows into the cavity 90 from the positions in the circumferential direction. This can cool the valve body 81 at the positions in the circumferential direction, and thus the temperature difference of the valve body 81 in the circumferential direction can be inhibited. This can increase temperature uniformity for the valve body 81 in the circumferential direction.

The dry air blown out of the holes 95 flows through the cavity 90 around the pipe member 91, and is exhausted outside the chamber 10 through the exhaust route 86. Thus, the shutter mechanism 80 can cool the valve body 81 by blowing the dry air supplied from the supply route 85 from the positions of the pipe member 91 in the circumferential direction, and exhausting the blown dry air from the exhaust route to circulate the dry air.

The embodiment has described an example in which the valve body 81 of the shutter mechanism 80 is cooled. However, this is not limiting. The structure of the valve body 81 in the embodiment may be used in the inner wall member of the chamber 10 to cool the inner wall member. For example, a cavity may be formed in the deposition shield such as the first deposition shield 71 or the second deposition shield 72 along the circumferential direction as in the valve body 81, and a pipe member may be disposed in the cavity to cool the deposition shield.

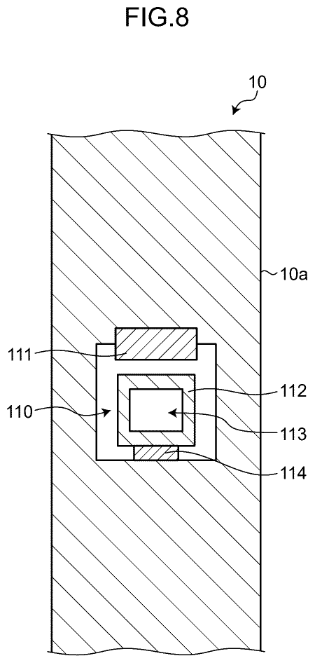

The structure of the valve body 81 in the embodiment may be used in the outer wall member of the chamber 10 to cool the outer wall member. For example, the structure of the valve body 81 in the embodiment may be used in the side wall 10a of the chamber 10 as the outer wall member to cool the side wall 10a. FIG. 8 is a diagram of an example of the structure of the side wall 10a of the chamber 10 in the embodiment. The side wall 10a is formed with a cavity 110. The cavity 110 is rectangular in cross section. The cavity 110 connects over one circumference along the circumferential direction of the chamber 10 to be formed in an annular shape. Inside the side wall 10a, a heater 111 is disposed. The heater 111 is disposed above the cavity 110. In the side wall 10a, a pipe member 112 is disposed in the cavity 110. The pipe member 112 is, along the cavity 110 of the side wall 10a, disposed in the cavity 110. The pipe member 112 is supported by supports 114 at a plurality of locations in the cavity 110. The pipe member 112 is constructed in the same manner as the pipe member 91, in which a cavity 113 is formed to flow a cooling gas, and holes communicating with the cavity 113 are formed at a plurality of positions in the circumferential direction. Dry air is supplied to the pipe member 112 from an unillustrated supply route. The supplied dry air flows through the cavity 113 of the pipe member 112, and blows out of the holes into the cavity 110. The dry air blown out of the holes flows through the cavity 110, and is exhausted from an unillustrated exhaust route communicating with the cavity 110. The side wall 10a supplies the dry air from the supply route to the pipe member 112, and blows the dry air from the positions of the pipe member 112 in the circumferential direction into the cavity 110, and thereby the side wall 10a can be cooled from the positions in the circumferential direction, and the temperature difference of the side wall 10a in the circumferential direction can be inhibited.

The embodiment has described a case in which the valve body 81 is temperature-controlled by cooling the valve body 81 by flowing the dry air through the cavity 90 and supplying power to the heater 87 to heat the valve body 81. However, this is not limiting. When the valve body 81 is sufficiently heated by heat input from the plasma, the heater 87 is not necessarily required to be provided.

The embodiment has described a case in which the pipe member 91 is disposed in a ring shape over the entire circumference of the cavity 90. However, this is not limiting. The pipe member 91 may be disposed discretely in the entire circumference of the cavity 90. For example, a plurality of arc-shaped pipe members 91 may be individually disposed in the cavity 90 of the valve body 81 in divided ranges in the circumferential direction, and the cooling gas may be supplied to the respective pipe members 91 from supply routes provided in the respective lifting/lowering mechanisms 82. The exhaust route may be provided in any one lifting/lowering mechanism 82, or provided for each of the lifting/lowering mechanisms 82.

The embodiment has described a case in which the cross-sectional shape of the cavity 90 and the cavity 110 is rectangular. However, this is not limiting. The cross-sectional shape of the cavity 90 and the cavity 110 may be any shape. For example, the cross-sectional shape of the cavity 90 and the cavity 110 may be any of circular, oval, and polygonal.

The embodiment has described a case in which the cross-sectional shape of the pipe member 91 and the pipe member 112 is rectangular. However, this is not limiting. The cross-sectional shape of the pipe member 91 and the pipe member 112 may be any shape. Note that the cross-sectional shape of the pipe member 91 and the pipe member 112 is preferably a shape similar to that of the cavity 90 and the cavity 110 in order to provide a gap around them and facilitate gas flow when disposed in the cavity 90 and the cavity 110.

The embodiment has described a case in which the cross-sectional shape of the cavity 93 and the cavity 113 is rectangular. However, this is not limiting. The cross-sectional shape of the cavity 93 and the cavity 113 may be any shape. Note that since the cavity 93 and the cavity 113 are formed in the pipe member 91 and the pipe member 112, respectively, they preferably have the same cross-sectional shape as the outer shape of the pipe member 91 and the pipe member 112.

As described above, the wall member in the embodiment has the wall member body (e.g., the valve body 81 and the side wall 10a) and the pipe member (e.g., the pipe member 91 and the pipe member 112). The wall member body is provided in the circumferential direction of the processing container (the chamber 10), and provided with the first cavity (e.g., the cavity 90 and the cavity 110) formed along the circumferential direction inside. The pipe member is disposed in the first cavity, formed of a member having lower thermal conductivity than the wall member body, provided with the second cavity (e.g., the cavity 93 and the cavity 113) formed to flow the cooling gas inside, and provided with the one or more holes (e.g., the holes 95) formed to cause the first cavity and the second cavity to communicate with each other. This can inhibit the temperature difference of the wall member in the circumferential direction.

The wall member body is the inner wall member (e.g., the valve body 81 and the deposition shield) of the processing container. This can inhibit the temperature difference of the inner wall member of the processing container in the circumferential direction.

The wall member body is the outer wall member (e.g., the side wall 10a) of the processing container. This can inhibit the temperature difference of the outer wall member of the processing container in the circumferential direction.

The wall member body (e.g., the valve body 81) is made capable of being lifted and lowered by being supported by a lifting/lowering mechanism capable of being lifted and lowered (e.g., the lifting/lowering mechanism 82), and is configured to supply the cooling gas from a supply route (e.g., the supply route 85) provided in the lifting/lowering mechanism to the second cavity (e.g., the cavity 93), and exhaust the cooling gas in the first cavity (e.g., the cavity 90) to an exhaust route (e.g., the exhaust route 86) provided in the lifting/lowering mechanism. This can cool the wall member while reducing an increase in the weight of the wall member compared to a case in which cooling is performed using a liquid such as a refrigerant.

The wall member body is formed of aluminum. The pipe member is formed of a resin. This can form the heat transfer properties of the wall member body to be high. In addition, by forming the pipe member of a resin, heat transfer to the cooling gas flowing in the second cavity can be reduced.

The wall member body is formed in a ring shape along the circumferential direction, and provided with the first cavity formed in a ring shape along the circumferential direction inside. The pipe member is disposed in a ring shape over the entire circumference of the first cavity, or is disposed discretely in the entire circumference of the first cavity. This can inhibit the temperature difference of the wall member in the circumferential direction.

The pipe member (e.g., the pipe member 91 and the pipe member 112) is formed to have a smaller cross section than the cross section of the first cavity (e.g., the cavity 90 and the cavity 110), supported by the supports (e.g., the supports 92 and the supports 114) at a plurality of locations on the lower surface, and disposed apart from the lower surface of the first cavity except at the supports. This can reduce heat transfer to the pipe member.

The pipe member is configured such that the diameter of the holes is formed larger as the distance from the supply port (e.g., the supply port 94) through which the cooling gas is supplied increases along the second cavity. This can further inhibit the temperature difference of the wall member in the circumferential direction.

The pipe member is configured such that the holes are formed at a shorter spacing as the distance from the supply port (e.g., the supply port 94) through which the cooling gas is supplied increases along the second cavity. This can further inhibit the temperature difference of the wall member in the circumferential direction.

The cooling gas is dry air. This can perform cooling while inhibiting the occurrence of condensation in the first cavity and the second cavity.

In the wall member body, the heater (the heater 87) is provided along the circumferential direction. The pipe member is provided with the holes formed closer to the heater. This can strongly cool the heater side of the valve body 81.

The embodiments disclosed here should be considered to be exemplary and not restrictive in all respects. The above embodiments may be omitted, replaced, or modified in various forms without departing from the accompanying claims and the gist thereof.

The embodiment described above has described an example in which the plasma processing apparatus performs etching as the plasma process. However, this is not limiting. The plasma process may be any process such as a film forming process or ashing.

With respect to the above embodiments, the following addendum is further disclosed.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures. The functionality of the elements disclosed herein may be implemented using circuitry or processing circuitry which includes general purpose processors, special purpose processors, integrated circuits, ASICS (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The present disclosure can inhibit the temperature difference of the wall member in the circumferential direction.

In connection with the above embodiment, the following notes are further disclosed.

### (Note 1)

A wall member comprising:
a wall member body provided in a circumferential direction of a processing container, and provided with a first cavity formed along the circumferential direction inside; and
a pipe member disposed in the first cavity, formed of a member having lower thermal conductivity than the wall member body, provided with a second cavity formed to flow a cooling gas inside, and provided with one or more holes formed to cause the first cavity and the second cavity to communicate with each other.

### (Note 2)

The wall member according to Note 1, wherein the wall member body is an inner wall member of the processing container.

### (Note 3)

The wall member according to Note 1 or 2, wherein the wall member body is an outer wall member of the processing container.

### (Note 4)

The wall member according to any one of Notes 1 to 3, wherein the wall member body is made capable of being lifted and lowered by being supported by a lifting/lowering mechanism capable of being lifted and lowered, and is configured to supply the cooling gas from a supply route provided in the lifting/lowering mechanism to the second cavity, and exhaust the cooling gas in the first cavity to an exhaust route provided in the lifting/lowering mechanism.

### (Note 5)

The wall member according to any one of Notes 1 to 4, wherein the wall member body is formed of aluminum.

### (Note 6)

The wall member according to any one of Notes 1 to 5, wherein the pipe member is formed of a resin.

### (Note 7)

The wall member according to any one of Notes 1 to 6, wherein
the wall member body is formed in a ring shape along the circumferential direction, and provided with the first cavity formed in a ring shape along the circumferential direction inside the wall member body, and
the pipe member is disposed in a ring shape over an entire circumference of the first cavity, or disposed discretely in the entire circumference of the first cavity.

### (Note 8)

The wall member according to any one of Notes 1 to 7, wherein the pipe member is supported by supports at a plurality of locations on a lower surface, and disposed apart from a lower surface of the first cavity except at the supports.

### (Note 9)

The wall member according to any one of Notes 1 to 8, wherein the pipe member is configured such that a diameter of the holes is formed larger as a distance from a supply port through which the cooling gas is supplied increases along the second cavity.

### (Note 10)

The wall member according to any one of Notes 1 to 9, wherein the pipe member is configured such that the holes are formed at a shorter spacing as a distance from a supply port through which the cooling gas is supplied increases along the second cavity.

### (Note 11)

The wall member according to any one of Notes 1 to 10, wherein the cooling gas is dry air.

### (Note 12)

The wall member according to any one of Notes 1 to 11, wherein
in the wall member body, a heater is provided along the circumferential direction, and
the pipe member is provided with the holes formed closer to the heater.

### (Note 13)

A plasma processing apparatus comprising a wall member according to any one of Notes 1 to 12.

What is claimed is:

1. A wall member comprising:
a wall member body provided in a circumferential direction of a processing container, and provided with a first cavity formed along the circumferential direction inside; and
a pipe member disposed in the first cavity, wherein the pipe member:
has a lower thermal conductivity than the wall member body,
is provided with a second cavity formed to flow a cooling gas inside, and
is provided with one or more holes formed to allow the first cavity and the second cavity to communicate with each other.

2. The wall member according to claim 1, wherein the wall member body is an inner wall member of the processing container.

3. The wall member according to claim 1, wherein the wall member body is an outer wall member of the processing container.

4. The wall member according to claim 1, wherein the wall member body is capable of being lifted and lowered by a lift, and
the wall member body is configured to supply the cooling gas from a supply route provided in the lift to the second cavity, and exhaust the cooling gas in the first cavity to an exhaust route provided in the lift.

5. The wall member according to claim 1, wherein the wall member body is formed of aluminum.

6. The wall member according to claim 1, wherein the pipe member is formed of a resin.

7. The wall member according to claim 1, wherein:
the wall member body is formed in a ring shape along the circumferential direction, and the wall member body is provided with the first cavity formed in a ring shape along the circumferential direction inside the wall member body, and
the pipe member is disposed in a ring shape over an entire circumference of the first cavity, or the pipe member is disposed discretely in the entire circumference of the first cavity.

8. The wall member according to claim 1, wherein the pipe member is supported by supports at a plurality of locations on a lower surface, and
the pipe member is disposed apart from a lower surface of the first cavity except at the supports.

9. The wall member according to claim 1, wherein a diameter of the one or more holes of the pipe member is formed larger as a distance from a supply port through which the cooling gas is supplied increases along the second cavity.

10. The wall member according to claim 1, wherein the one or more holes of the pipe member are formed at a shorter spacing as a distance from a supply port through which the cooling gas is supplied increases along the second cavity.

11. The wall member according to claim 1, wherein the cooling gas is dry air.

12. The wall member according to claim 1, further comprising:
a heater is provided along the circumferential direction in the wall member body, and
the pipe member is provided with the holes formed closer to the heater.

13. A plasma processing apparatus comprising a wall member according to claim 1.

14. A plasma processing apparatus comprising:
a processing container; and
a wall member including:
a wall member body provided in a circumferential direction of a processing container, and provided with a first cavity formed along the circumferential direction inside; and
a pipe member disposed in the first cavity,
wherein the pipe member:
has a lower thermal conductivity than the wall member body,
is provided with a second cavity formed to flow a cooling gas inside, and
is provided with one or more holes formed to cause the first cavity and the second cavity to communicate with each other.

15. The plasma processing apparatus according to claim 14, wherein the wall member is an inner wall member or an outer wall member of the processing container.

16. The plasma processing apparatus according to claim 14, further comprising:
a lift configured to move the wall member body along a vertical direction,
wherein the wall member body is configured to supply the cooling gas from a supply route provided in the lift to the second cavity, and exhaust the cooling gas in the first cavity to an exhaust route provided in the lift.

17. The plasma processing apparatus according to claim 14,
wherein the wall member body is formed of aluminum, and
the pipe member is formed of a resin.

18. The plasma processing apparatus according to claim 14, wherein:
the wall member body is formed in a ring shape along the circumferential direction, and the wall member body is provided with the first cavity formed in a ring shape along the circumferential direction inside the wall member body, and
the pipe member is disposed in a ring shape over an entire circumference of the first cavity, or the pipe member is disposed discretely in the entire circumference of the first cavity.

19. The plasma processing apparatus according to claim 14, further comprising:
a heater is provided along the circumferential direction in the wall member body, and
the pipe member is provided with the holes formed closer to the heater.

20. A plasma processing apparatus comprising:
a processing container defining a plasma processing space;
a gas supply configured to supply a processing gas into the plasma processing space;
a radio frequency power supply configured to supply radio frequency power to generate plasma from the processing gas in the plasma processing space;
a susceptor disposed in the processing container and configured to support a substrate;
a wall member including:
a first deposition shield;
a second deposition shield;
a wall member body provided in a circumferential direction of a processing container, and provided with a first cavity formed along the circumferential direction inside; and
a pipe member disposed in the first cavity; and
a lift configured to move the wall member body along a vertical direction to open and close a space between the first deposition shield and the second deposition shield,
wherein the pipe member:
has a lower thermal conductivity than the wall member body,
is provided with a second cavity formed to flow a cooling gas inside, and
is provided with one or more holes formed to cause the first cavity and the second cavity to communicate with each other.
